(19) United States
(12) Patent Application Publication
(10) Pub. No.: US 2009/0176080 A1
(43) Pub. Date: Jul. 9, 2009

(54) STIFFENER AND STRENGTHENED FLEXIBLE PRINTED CIRCUIT BOARD HAVING THE SAME

(75) Inventors: Yung-Wei Lai, Tayuan (TW); Cheng-Wei Kuo, Tayuan (TW); Shing-Tza Liou, Tayuan (TW)

Correspondence Address: PCE INDUSTRY, INC.;ATT. Steven Reiss, 458 E. LAMBERT ROAD, FULLERTON, CA, 92835, US

(73) Assignee: FOXCONN ADVANCED TECHNOLOGY INC., Tayuan (TW)

(21) Appl. No.: 12/140,480

(22) Filed: Jun. 17, 2008

(30) Foreign Application Priority Data
Jan. 4, 2008 (TW) 097100306

(51) Int. Cl. B32B 33/00; B32B 5/00; C08G 16/00; H05K 1/00

(52) U.S. Cl. 428/220; 428/343; 428/335; 428/354; 528/220; 174/254

(57) ABSTRACT

An exemplary stiffener includes at least one polyethylene naphthalate layer. The at least one polyethylene naphthalate layer is represented by the following formula:

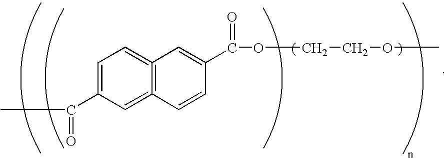

### BACKGROUND

1. Technical Field

The present invention relates to flexible printed circuit boards, particularly to a stiffener and a strengthened flexible printed circuit board having the stiffener.

2. Description of related art

In recent years, electronic products have achieved miniaturization in volume and diversification in function. Flexible printed circuit boards (FPCBs) are widely used for electrical connection because of their flexibility and lightness.

Typically, a mass of electronic components are mounted onto a surface of a flexible printed circuit board to achieve various functions. For mounting and supporting the electronic components, a stiffener made of polyimide (PI) is usually attached onto the rear of the flexible printed circuit board via an adhesive layer to increase mechanical strength of the flexible printed circuit board, thereby obtaining a strengthened flexible printed circuit board. However, the strengthened flexible printed circuit board with the polyimide stiffener still has not enough mechanical strength to mount a mass of electronic components thereon. In addition, high cost of the polyimide stiffener may increase the cost of manufacturing the strengthened flexible printed circuit board.

What is needed, therefore, is a stiffener and a strengthened flexible printed circuit board having the stiffener so as to increase mechanical strength of the flexible printed circuit board and lower cost of manufacturing the flexible printed circuit board with high mechanical strength.

### SUMMARY

One present embodiment provides a stiffener. The stiffener includes at least one polyethylene naphthalate layer. The at least one polyethylene naphthalate layer is represented by the following general formula:

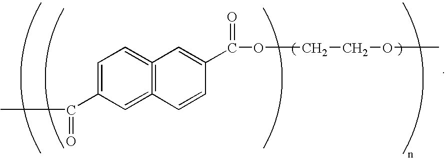

Another present embodiment provides a strengthened flexible printed circuit board. The strengthened flexible printed circuit board includes a flexible printed circuit board and a stiffener attached onto the flexible printed circuit board. The stiffener includes at least one polyethylene naphthalate layer. The at least one polyethylene naphthalate layer is represented by the following general formula:

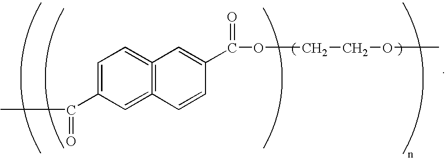

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic, cross-sectional view of a stiffener according to a first embodiment.

FIG. 2 is a schematic, cross-sectional view of a stiffener according to a second embodiment.

FIG. 3 is a schematic, cross-sectional view of a stiffener according to a third embodiment.

FIG. 4 is a schematic, cross-sectional view of a stiffener according to a fourth embodiment.

FIG. 5 is a schematic, cross-sectional view of a strengthened flexible printed circuit board with the stiffener shown in FIG. 1.

FIG. 6 is a schematic, cross-sectional view of a strengthened flexible printed circuit board with the first stiffener shown in FIG. 3.

FIG. 7 is a schematic, cross-sectional view of a strengthened flexible printed circuit board with the first stiffener shown in FIG. 4.

### DETAILED DESCRIPTION OF THE EMBODIMENTS

Embodiments will now be described in detail below with reference to the drawings.

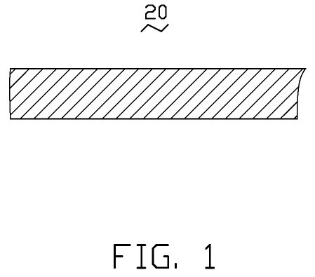

Referring to FIG. 1, a stiffener 20 according to a first embodiment is shown.

The stiffener 20 has a thickness in a range from 25 to 250 microns. Thus, the stiffener 20 has adequate rigidity to increase mechanical strength of a flexible printed circuit board and has adequate flexibility to maintain flexibility of a strengthened flexible printed circuit board with the stiffener 20 for a roll-to-roll process.

The stiffener 20 is comprised of a polyethylene naphthalate (PEN) represented by the following general formula:

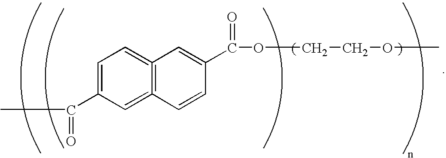

The polyethylene naphthalate can be prepared from ethylene glycol and one or more naphthalene dicarboxylic acids by condensation polymerization. The polyethylene naphthalate has a number of naphthalene rings in the molecular structure thereof. The naphthalene rings can increase rigidity of the molecular structure. Thus, the polyethylene naphthalate has good mechanical strength and structure stability. Moreover, coefficient of thermal expansion (CTE) for the polyethylene naphthalate is in a range from 18×10⁻⁶ to 20×10⁻⁶ K⁻¹. In general, coefficient of thermal expansion for the polyimide is in a range from 18×10⁻⁶ to 28×10⁻⁶ K⁻¹. Therefore, the polyethylene naphthalate has similar thermal expansion property to the polyimide, and has good thermal resistance and thermal stability. In addition, the polyethylene naphthalate has a lower cost than the polyimide. Cost of manufacturing the flexible printed circuit board with high mechanical strength can be reduced correspondingly.

The stiffener 20 can includes an adhesive layer adhered thereto. Additionally, a stiffener can include a number of polyethylene naphthalate layers and a number of adhesive layers arranged in an alternate fashion, thereby forming a multilayer structure to further increase mechanical strength of the stiffener.

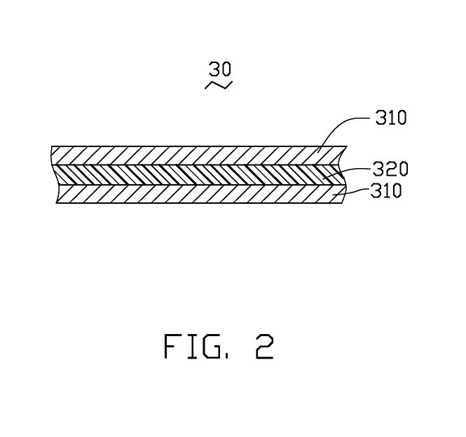

Referring to FIG. 2, a stiffener 30 according to a second embodiment is shown. The stiffener 30 includes two polyethylene naphthalate layers 310 and an adhesive layer 320 sandwiched between the two polyethylene naphthalate layers 310. The adhesive layer 320 is configured for adhering to the two polyethylene naphthalate layers 310 adjacent thereto. The two polyethylene naphthalate layers 310 are configured for adhering to a flexible printed circuit board. Each of the polyethylene naphthalate layers 310 has a thickness in a range from 25 to 75 microns. The adhesive layer 320 has a thickness in a range from 25 to 75 microns. Thus, the stiffener 30 has adequate rigidity to increase mechanical strength of a flexible printed circuit board and has adequate flexibility to maintain flexibility of a strengthened flexible printed circuit board with the stiffener 30 to be suitable for a roll-to-roll process.

The polyethylene naphthalate layers 310 are represented by the following general formula:

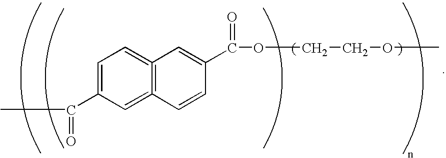

The adhesive layer 320 can be comprised of a material selected from a thermoplastic adhesive and an ultraviolet-curable adhesive.

It is noted that the stiffener 30 can includes a number of polyethylene naphthalate layers 310 and a number of adhesive layers 320 arranged in an alternate fashion. The number of layers of the polyethylene naphthalate layers 310 is one greater than that of the adhesive layers 320. Each of the adhesive layers 320 is disposed between the two polyethylene naphthalate layers 310 adjacent thereto and is configured for adhering to the two polyethylene naphthalate layers 310. Thus, the stiffener 30 contains two polyethylene naphthalate layers 310 on two opposite outer sides thereof, respectively. Each of the two polyethylene naphthalate layers 310 on two opposite outer sides of the stiffener 30 is configured for adhering to the flexible printed circuit board. The total thickness of the stiffener 30 is in a range from 75 to 250 microns.

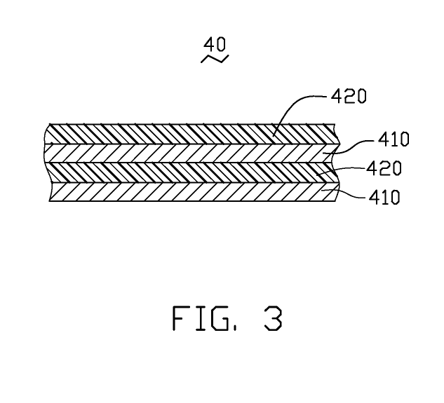

Referring to FIG. 3, a stiffener 40 according to a third embodiment is shown. The stiffener 40 also includes a number of polyethylene naphthalate layers 410 and a number of adhesive layers 420 arranged in an alternate fashion. The number of layers of the polyethylene naphthalate layers 410 is equal to that of the adhesive layers 420. Thus, the stiffener 40 has one polyethylene naphthalate layer 410 and one adhesive layer 420 on two opposite outer sides thereof, respectively. The one polyethylene naphthalate layer 410 and the one adhesive layer 420 on two opposite outer sides of the stiffener 40 are configured for adhering to a flexible printed circuit board. Each of the polyethylene naphthalate layers 410 has a thickness in a range from 25 to 75 microns. Each of the adhesive layers 420 has a thickness in a range from 25 to 75 microns. The total thickness of the stiffener 40 is in a range from 50 to 250 microns. Thus, the stiffener 40 has adequate rigidity to increase mechanical strength of a flexible printed circuit board and has adequate flexibility to maintain flexibility of a strengthened flexible printed circuit board with the stiffener 40 to be suitable for a roll-to-roll process. In the present embodiment, the stiffener 40 includes two polyethylene naphthalate layers 410 and two adhesive layers 420 arranged alternately.

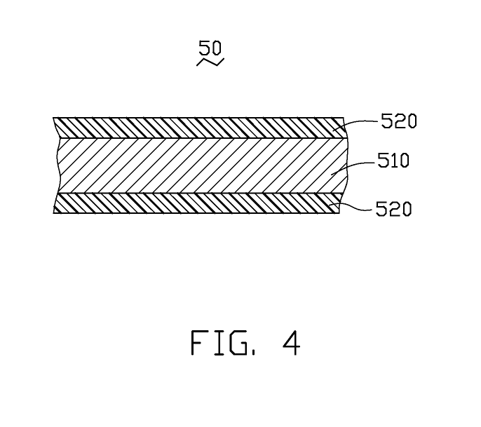

Referring to FIG. 4, a stiffener 50 according to a fourth embodiment is shown. The stiffener 50 includes a number of polyethylene naphthalate layers 510 and a number of adhesive layers 520 arranged in an alternate fashion. The number of layers of the polyethylene naphthalate layers 510 is one less than that of the adhesive layers 520. Thus, the stiffener 50 has two adhesive layers 520 on two opposite outer sides thereof respectively. The adhesive layers 520 on two opposite outer sides of the stiffener 50 are configured for adhering to a flexible printed circuit board. Each of the polyethylene naphthalate layers 510 has a thickness in a range from 25 to 75 microns. Each of the adhesive layers 520 has a thickness in a range from 25 to 75 microns. The total thickness of the stiffener 50 is in a range from 75 to 250 microns. Thus, the stiffener 50 has adequate rigidity to increase mechanical strength of a flexible printed circuit board and has adequate flexibility to maintain flexibility of a strengthened flexible printed circuit board with the stiffener 50 to be suitable for a roll-to-roll process. In the present embodiment, the stiffener 50 includes two adhesive layers 520 and a polyethylene naphthalate layer 510 sandwiched between the two adhesive layers 520.

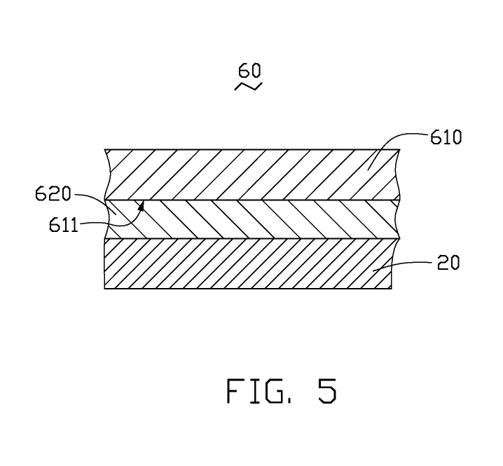

Referring to FIG. 5, a strengthened flexible printed circuit board 60 with the stiffener 20 is shown. The strengthened flexible printed circuit board 60 includes a flexible printed circuit board 610, an adhering layer 620 and the stiffener 20. The flexible printed circuit board 60 has a strengthening surface 611. The adhering layer 620 is adhered to the strengthening surface 611 and is sandwiched between the flexible printed circuit board 610 and the stiffener 20, thus the stiffener 20 is attached on the flexible printed circuit board 60 via the adhering layer 620. The adhering layer 620 can be comprised of a material selected from a thermoplastic adhesive and an ultraviolet-curable adhesive. The adhering layer 620 has a thickness in a range from 25 to 75 microns. Thus, the adhering layer 620 will not affect flexibility of the strengthened flexible printed circuit board 60 with the stiffener 20 to be suitable for a roll-to-roll process.

It is noted that the stiffener 30, 40, 50 can be used as a substitute of the stiffener 20 of the strengthened flexible printed circuit board 60 so as to increase mechanical strength of the flexible printed circuit board 610.

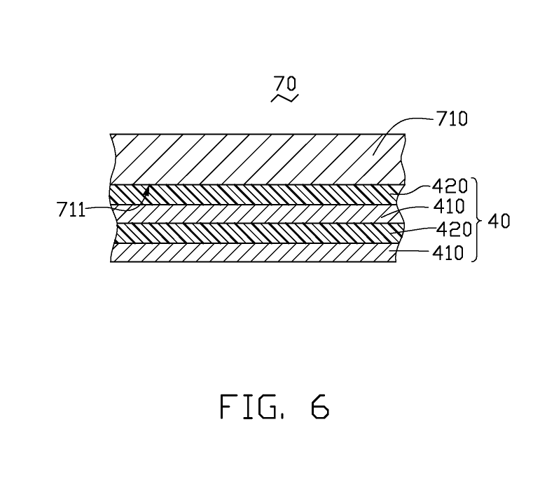

Referring to FIG. 6, a strengthened flexible printed circuit board 70 with the stiffener 40 is shown. The strengthened flexible printed circuit board 710 includes a flexible printed circuit board 710 and the stiffener 40. The flexible printed circuit board 710 has a strengthening surface 711. The adhesive layer 420 on the outer side of the stiffener 40 is directly adhered to the strengthening surface 711, and thus the stiffener 40 is attached onto the flexible printed circuit board 710.

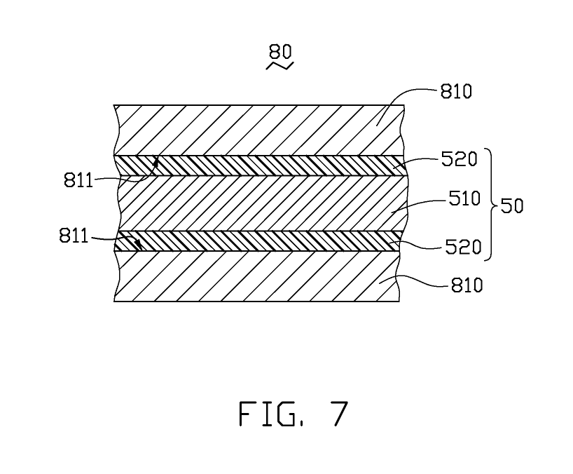

Referring to FIG. 7, a strengthened flexible printed circuit board 80 with the stiffener 50 is shown. The strengthened flexible printed circuit board 80 includes a flexible printed circuit board 810 and the stiffener 50. The flexible printed circuit board 810 is bent so as to form two strengthening surfaces 811 face to face. The two adhesive layers 520 on the outer sides of the stiffener 50 are directly adhered to the two strengthening surfaces 811, respectively. Thus, the stiffener 50 is attached onto the flexible printed circuit board 810 to fix the bent flexible printed circuit board 810.

It is noted that one adhesive layer 520 on the outer side of the stiffener 50 can adheres to a flexible printed circuit board, another adhesive layer 520 on the outer sides of the stiffener 50 can adheres to other component such as a rigid printed circuit board, a support and an electronic component.

It is also note that the stiffener 20, 30,40, 50 can be used to adhere to other flexible substrates such as a flexible copper and a copper clad laminate to increase mechanical strength of the flexible substrates. Thus, due to the strength of the flexible substrates is increased, processing of the strengthened flexible substrates become easy.

While certain embodiments have been described and exemplified above, various other embodiments will be apparent to those skilled in the art from the foregoing disclosure. The present invention is not limited to the particular embodiments described and exemplified but is capable of considerable variation and modification without departure from the scope of the appended claims.

What is claimed is:

1. A stiffener, comprising:
at least one polyethylene naphthalate layer represented by the following general formula:

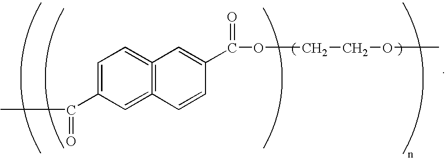

2. The stiffener as claimed in claim 1, wherein a thickness of each polyethylene naphthalate layer is in a range from 25 to 75 microns.

3. The stiffener as claimed in claim 1, wherein a total thickness of the stiffener is in a range from 25 to 250 microns.

4. The stiffener as claimed in claim 1, further comprising at least one adhesive layer adhered to the at least one polyethylene naphthalate layer.

5. The stiffener as claimed in claim 4, wherein the at least one adhesive layer includes a plurality of adhesive layers, and the at least one polyethylene naphthalate layer includes a plurality of polyethylene naphthalate layers, the adhesive layers and the polyethylene naphthalate layers arranged in an alternate fashion.

6. The stiffener as claimed in claim 5, wherein a thickness of each of the adhesive layers is in a range from 25 to 75 microns.

7. The stiffener as claimed in claim 5, wherein the adhesive layers are comprised of a material selected from a group consisting of a thermoplastic adhesive and an ultraviolet-curable adhesive.

8. The stiffener as claimed in claim 5, wherein the number of the polyethylene naphthalate layers is one greater than that of the adhesive layers.

9. The stiffener as claimed in claim 5, wherein the number of the polyethylene naphthalate layers is equal to that of the adhesive layers.

10. The stiffener as claimed in claim 5, wherein the number of the polyethylene naphthalate layers is one less than that of the adhesive layers.

11. A strengthened flexible printed circuit board, comprising:
a flexible printed circuit board; and
a stiffener attached on the flexible printed circuit board, the stiffener comprising at least one polyethylene naphthalate layer represented by the following general formula:

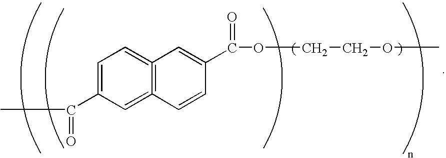

12. The strengthened flexible printed circuit board, as claimed in claim 11, wherein a thickness of the at least one polyethylene naphthalate layer is in a range from 25 to 75 microns.

13. The strengthened flexible printed circuit board as claimed in claim 11, wherein a total thickness of the stiffener is in a range from 25 to 250 microns.

14. The strengthened flexible printed circuit board as claimed in claim 11, further comprising an adhering layer sandwiched between the flexible printed circuit board and the stiffener.

15. The strengthened flexible printed circuit board as claimed in claim 14, wherein a thickness of the adhering layer is in a range from 25 to 75 microns.

16. The strengthened flexible printed circuit board as claimed in claim 11, wherein the stiffener further comprises at least one adhesive layer adhered to the at least one polyethylene naphthalate layer, the at least one adhesive layer includes a plurality of adhesive layers, the at least one polyethylene naphthalate layer includes a plurality of polyethylene naphthalate layers, and the adhesive layers and the polyethylene naphthalate layers arranged in an alternate fashion.

17. The strengthened flexible printed circuit board as claimed in claim 16, wherein the number of layers of the polyethylene naphthalate layers is one greater than that of the adhesive layers.

18. The strengthened flexible printed circuit board as claimed in claim 16, wherein the number of layers of the polyethylene naphthalate layers is equal to that of the adhesive layers, and one outside adhesive layer is adhered to the flexible printed circuit board.

19. The strengthened flexible printed circuit board as claimed in claim 16, wherein the number of layers of the polyethylene naphthalate layers is one less than that of the adhesive layers.

20. A strengthened flexible article, comprising:
a flexible substrate; and
a stiffener attached on the flexible substrate, the stiffener comprising at least one polyethylene naphthalate layer represented by the following general formula: [chemical structure]
